(19) United States
(12) Patent Application Publication
(10) Pub. No.: US 2025/0379029 A1
(43) Pub. Date: Dec. 11, 2025

(54) MULTI-CHARGED PARTICLE BEAM WRITING METHOD

(71) Applicant: NuFlare Technology, Inc., Yokohama-shi (JP)

(72) Inventors: Jumpei YASUDA, Kamakura-shi (JP); Haruyuki NOMURA, Yokohama-shi (JP); Hiroshi MATSUMOTO, Yokohama-shi (JP)

(73) Assignee: NuFlare Technology, Inc., Yokohama-shi (JP)

(21) Appl. No.: 19/210,439

(22) Filed: May 16, 2025

(30) Foreign Application Priority Data
Jun. 6, 2024 (JP) 2024-092453

(51) Int. Cl. H01J 37/317; H01J 37/04; H01J 37/304

(52) U.S. Cl. CPC H01J 37/3177; H01J 37/045; H01J 37/3045; H01J 2237/0437; H01J 2237/30472; H01J 2237/31764

(57) ABSTRACT

A multi-charged-particle-beam-writing-method includes calculating, for each of some shots, the first positional-deviation-shift-amount depending on the number of blanking beams of a shot concerned, shifted from a design position of the multiple-charged-particle-beams, determining, for each of some shots, whether there is a shot with respect to which the first positional-deviation-shift-amount exceeds a threshold, calculating, in the case where a shot exceeding the threshold exists, the number of blanking beams controlled to be beam-off in remaining shots in all shots, calculating the second positional-deviation-shift-amount depending on a calculated number of blanking beams in all shots, shifted from the design position of the multiple-charged-particle-beams, and calculating a correction amount for an irradiation position of each shot, based on a calculated second positional-deviation-shift-amount.

### CROSS-REFERENCE TO RELATED APPLICATION

This application is based upon and claims the benefit of priority from prior Japanese Patent Application No. 2024-092453 filed on Jun. 6, 2024 in Japan, the entire contents of which are incorporated herein by reference.

### BACKGROUND OF THE INVENTION

### Field of the Invention

Embodiments of the present invention relate to a multi-charged particle beam writing method, and, for example, to a method for correcting positional deviation occurring on the substrate surface in multi-beam writing.

### Description of Related Art

The lithography technique which advances miniaturization of semiconductor devices is extremely important as a unique process in which patterns are formed in semiconductor manufacturing.: In recent years, with high integration of LSI, the line width (critical dimension) necessary for semiconductor device circuits is decreasing year by year. The electron beam writing technique, which intrinsically has excellent resolution, is used for writing or “drawing” patterns on a wafer and the like with electron beams.

For example, as a known example of employing the electron beam writing technique, there is a writing apparatus using multiple beams. Since writing with multiple beams can apply a lot of beams at a time, the writing throughput can be greatly increased compared to writing with a single electron beam. For example, a writing apparatus employing the multiple beam system forms multiple beams by letting an electron beam emitted from an electron gun pass through a mask having a plurality of holes, performs blanking control for each beam, reduces each unblocked beam to generate a reduced mask image by an optical system, and deflects, by a deflector, a reduced beam to be applied to a desired position on a target object or “sample”.

In multi-beam writing, since writing is executed while individually performing blanking processing on multiple beams, the number of beams to be blanking-processed changes during the writing. When the number of beams changes, the total current amount also changes, which results in generating a so-called beam blur due to the Coulomb effect, etc., or shifting of the beam irradiation position due to charging in the column. Since such a change of the number of beams individually occurs for each shot, it is desirable to perform position correction on each shot. Regarding writing processing, there are two cases: one is to write a chip pattern for which all the shots individually need to be corrected as described above, and the other is to write a chip pattern for which correction processing is unnecessary or simple correction can be allowed. Actually, the case of no correction or simple correction is more often than the case of correcting each shot. If, whenever writing processing is performed, all the shots are individually corrected each time regardless of contents of writing processing of a chip pattern, a large load is applied to calculation processing.

There is disclosed a method in which, based on a parameter relevant to shots, position correction is collectively performed for all the multiple beams of each shot (e.g., refer to Japanese Patent Application Laid-open (JP-A) No. 2021-132065).

### BRIEF SUMMARY OF THE INVENTION

According to one aspect of the present invention, a multi-charged particle beam writing method includes
calculating, using shot data of multiple charged particle beams, a number of blanking beams controlled to be beam-off in some shots in all shots of the multiple charged particle beams to be applied to a substrate,
calculating, for each shot of the some shots, a first positional deviation shift amount depending on the number of blanking beams of a shot concerned, shifted from a design position of the multiple charged particle beams,
determining, for the each shot of the some shots, whether there is a shot with respect to which the first positional deviation shift amount exceeds a threshold value,
calculating, in a case of there being a shot exceeding the threshold value, a number of blanking beams controlled to be beam-off in remaining shots in the all shots,
calculating a second positional deviation shift amount depending on a calculated number of blanking beams in the all shots, shifted from the design position of the multiple charged particle beams,
calculating a correction amount for an irradiation position of the each shot, based on a calculated second positional deviation shift amount, and
applying a shot of the multiple charged particle beams to the irradiation position of the each shot, which has been corrected using a calculated correction amount.

According to another aspect of the present invention, a multi-charged particle beam writing method includes
acquiring, using pattern data defining a plurality of figure patterns, a pattern density of each of a plurality of regions obtained by dividing a writing region of a substrate,
calculating, for the each of the plurality of regions, a first positional deviation shift amount depending on the pattern density, shifted from a design position of multiple charged particle beams, in a case of applying a shot to the substrate with the multiple charged particle beams,
determining, for the each of the plurality of regions, whether there is a region with respect to which the first positional deviation shift amount exceeds a threshold value,
calculating, in a case of there being a region exceeding the threshold value, a number of blanking beams controlled to be beam-off in all shots to be applied to the substrate with the multiple charged particle beams,
calculating a second positional deviation shift amount depending on a calculated number of blanking beams, shifted from the design position of the multiple charged particle beams,
calculating, in a case of there being the first positional deviation shift amount exceeding the threshold value, a correction amount for an irradiation position of each shot, based on the second positional deviation shift amount in a shot concerned, with respect to the all shots, and
applying a shot of the multiple charged particle beams to the irradiation position of the each shot, which has been corrected using a calculated correction amount.

### BRIEF DESCRIPTION OF THE DRAWINGS

FIG. 1 is an illustration showing a schematic diagram of a configuration of a writing apparatus according to a first embodiment;

FIG. 2 is a conceptual diagram showing a configuration of a shaping aperture array substrate according to the first embodiment;

FIG. 3 is a sectional view showing a configuration of a blanking aperture array mechanism according to the first embodiment;

FIG. 4 is a conceptual diagram for explaining an example of a writing operation according to the first embodiment;

FIG. 5 is an illustration showing an example of an irradiation region of multiple beams and a writing target pixel according to the first embodiment;

FIG. 6 is an illustration for explaining an example of a multi-beam writing operation according to the first embodiment;

FIG. 7 is an illustration showing an example of a beam pitch and a pattern pitch according to the first embodiment;

FIG. 8 is an illustration showing another example of a beam pitch and a pattern pitch according to the first embodiment;

FIG. 9 is an illustration showing another example of a beam pitch and a pattern pitch according to the first embodiment;

FIG. 10 is an illustration showing an example of a region where a pattern density is specifically high according to the first embodiment;

FIG. 11 is a flowchart showing an example of main steps of a writing method according to the first embodiment;

FIG. 12 is an illustration showing an example of a stripe layer of multiple writing according to the first embodiment;

FIG. 13 is an illustration showing an example of a sub-irradiation region according to the first embodiment;

FIG. 14 is an illustration showing an example of a relationship between a shift amount and the number of blanking beams according to the first embodiment;

FIG. 15 is an illustration showing another example of a relationship between a shift amount and the number of blanking beams according to the first embodiment;

FIG. 16 is an illustration for explaining an example of a correction method according to the first embodiment;

FIG. 17 is a flowchart showing an example of main steps of a writing method according to a modified example of the first embodiment;

FIG. 18 is a conceptual diagram showing a configuration of a writing apparatus according to a second embodiment;

FIG. 19 is a flowchart showing an example of main steps of a writing method according to the second embodiment; and

FIG. 20 is a flowchart showing an example of main steps of a writing method according to a modified example of the second embodiment.

### DETAILED DESCRIPTION OF THE INVENTION

Embodiments of the present invention provide a method which can reduce a load on calculation processing with respect to coping with positional deviation depending on the number of beams for each shot in multi-beam writing.

Embodiments of the present invention describe a configuration in which an electron beam is used as an example of a charged particle beam. The charged particle beam is not limited to the electron beam, and other charged particle beams such as an ion beam may also be used.

### First Embodiment

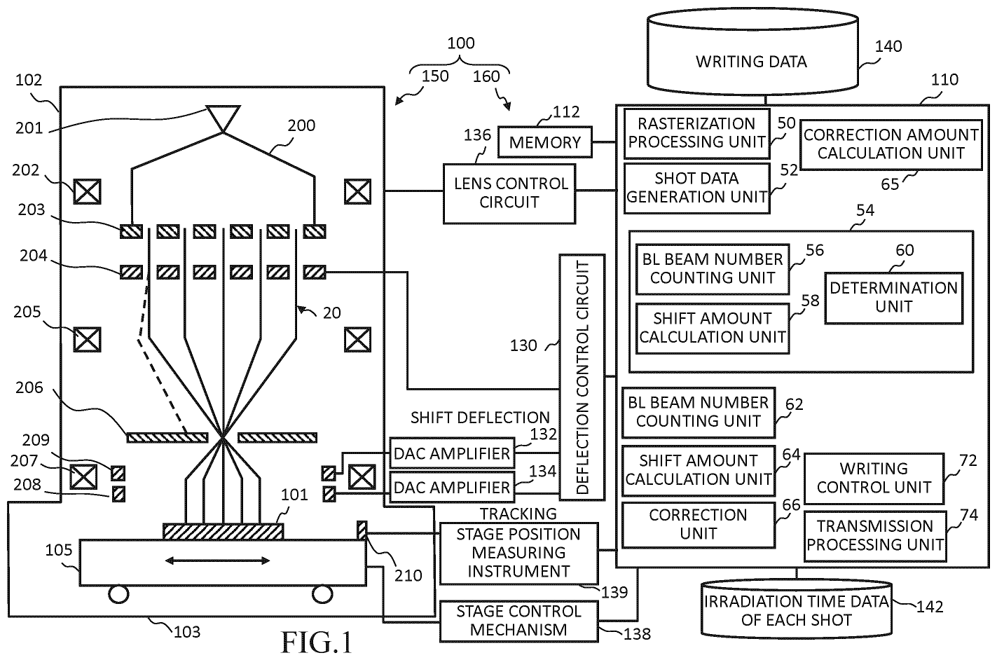

FIG. 1 is an illustration showing a schematic diagram of a configuration of a writing or “drawing” apparatus according to a first embodiment. As shown in FIG. 1, a writing apparatus 100 includes a writing mechanism 150 and a control system circuit 160. The writing apparatus 100 is an example of a multiple charged particle beam writing apparatus and an example of a multiple charged particle beam exposure apparatus. The writing mechanism 150 includes an electron optical column 102 (electron beam column) and a writing chamber 103. In the electron optical column 102, there are disposed an electron gun 201, an illumination lens 202, a shaping aperture array substrate 203, a blanking aperture array mechanism 204, a reducing lens 205, a limiting aperture substrate 206, an objective lens 207, a main deflector 208, and a sub deflector 209.

In the writing chamber 103, an XY stage 105 is disposed. On the XY stage 105, there is placed a target object or “sample” 101, such as a mask, serving as a writing target substrate when writing (exposure) is performed. For example, the target object 101 is an exposure mask used in fabricating semiconductor devices, or a semiconductor substrate (silicon wafer) for fabricating semiconductor devices. The target object 101 may be a mask blank on which resist has been applied and nothing has yet been written. On the XY stage 105, a mirror 210 for measuring the position of the XY stage 105 is placed.

The control system circuit 160 includes a control computer 110, a memory 112, a deflection control circuit 130, digital-analog converter (DAC) amplifier units 132 and 134, a lens control circuit 136, a stage control mechanism 138, a stage position measuring instrument 139, and storage devices 140 and 142 such as magnetic disk drives. The control computer 110, the memory 112, the deflection control circuit 130, the lens control circuit 136, the stage control mechanism 138, the stage position measuring instrument 139, and the storage devices 140 and 142 are connected to each other through a bus (not shown). The DAC amplifier units 132 and 134 and the blanking aperture array mechanism 204 are connected to the deflection control circuit 130. The sub deflector 209 is composed of at least four electrodes (or “at least four poles”), and controlled by the deflection control circuit 130 through the DAC amplifier 132 disposed for each electrode. The main deflector 208 is composed of at least four electrodes (or “at least four poles”), and controlled by the deflection control circuit 130 through the DAC amplifier 134 disposed for each electrode. Lenses, such as the illumination lens 202, the reducing lens 205, and the objective lens 207 are controlled by the lens control circuit 136.

The position of the XY stage 105 is controlled by the drive of each axis motor (not shown) which is controlled by the stage control mechanism 138. Based on the principle of laser interferometry, the stage position measurement instrument 139 measures the position of the XY stage 105 by receiving a reflected light from the mirror 210.

In the control computer 110, there are arranged a rasterization processing unit 50, a shot data generation unit 52, an estimation unit 54, a blanking beam number counting unit 62, a shift amount calculation unit 64, a correction amount calculation unit 65, a correction unit 66, a writing control unit 72, and a transmission processing unit 74. In the estimation unit 54, there are arranged a blanking beam number counting unit 56, a shift amount calculation unit 58, and a determination unit 60. Each of the “ . . . units” such as the rasterization processing unit 50, the shot data generation unit 52, the estimation unit 54 (the blanking beam number counting unit 56, the shift amount calculation unit 58, and the determination unit 60), the blanking beam number counting unit 62, the shift amount calculation unit 64, the correction amount calculation unit 65, the correction unit 66, the writing control unit 72, and the transmission processing unit 74 includes processing circuitry. The processing circuitry includes, for example, an electric circuit, a computer, a processor, a circuit board, a quantum circuit, a semiconductor device, or the like. Each “ . . . unit” may use common processing circuitry (the same processing circuitry), or different processing circuitry (separate processing circuitry). Information input/output to/from the rasterization processing unit 50, the shot data generation unit 52, the estimation unit 54 (the blanking beam number counting unit 56, the shift amount calculation unit 58, and the determination unit 60), the blanking beam number counting unit 62, the shift amount calculation unit 64, the correction amount calculation unit 65, the correction unit 66, the writing control unit 72, and the transmission processing unit 74, and information being operated are stored in the memory 112 each time.

Writing operations of the writing apparatus 100 are controlled by the writing control unit 72. In other words, the writing control unit 72 (an example of a control circuit) controls the writing mechanism 150. Processing of transmitting irradiation time data of each shot to the deflection control circuit 130 is controlled by the transmission control unit 74.

Writing data (chip data) is input from the outside of the writing apparatus 100, and stored in the storage device 140. Chip data defines information on a plurality of figure patterns configuring a chip pattern. Specifically, for example, coordinates for each vertex are defined in the order of configuration of the figure, for each figure pattern. Alternatively, for example, a figure code, coordinates, a size, and the like are defined for each figure pattern.

FIG. 1 shows a configuration necessary for describing the first embodiment. Other configuration elements generally necessary for the writing apparatus 100 may also be included therein.

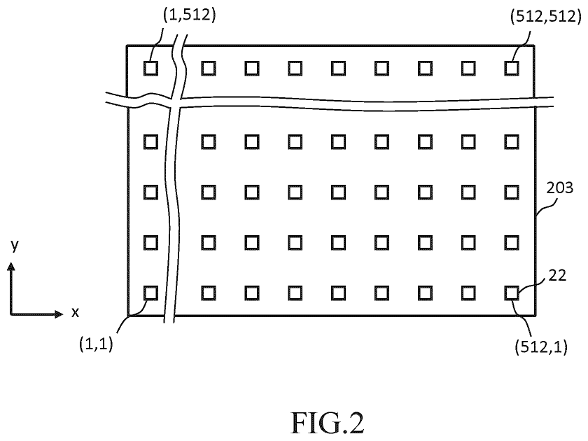

FIG. 2 is a conceptual diagram showing a configuration of a shaping aperture array substrate according to the first embodiment. As shown in FIG. 2, holes (openings) 22 of p rows long (length in the y direction) and q columns wide (width in the x direction) (p≥2, q≥2) are formed, like a matrix, at a predetermined arrangement pitch in the shaping aperture array substrate 203. In the case of FIG. 2, for example, holes 22 of 512×512, that is 512 holes in the y direction and 512 holes in the x direction, are formed. The number of the holes 22 is not limited thereto. For example, it is also preferable to form the holes 22 of 32×32. Each of the holes 22 is a rectangle (including square) having the same dimension and shape as each other. Alternatively, each of the holes 22 may be a circle with the same diameter as each other. The multiple beams 20 are formed by letting portions of an electron beam 200 individually pass through a corresponding one of a plurality of holes 22. In other words, the shaping aperture array substrate 203 forms the multiple beams 20.

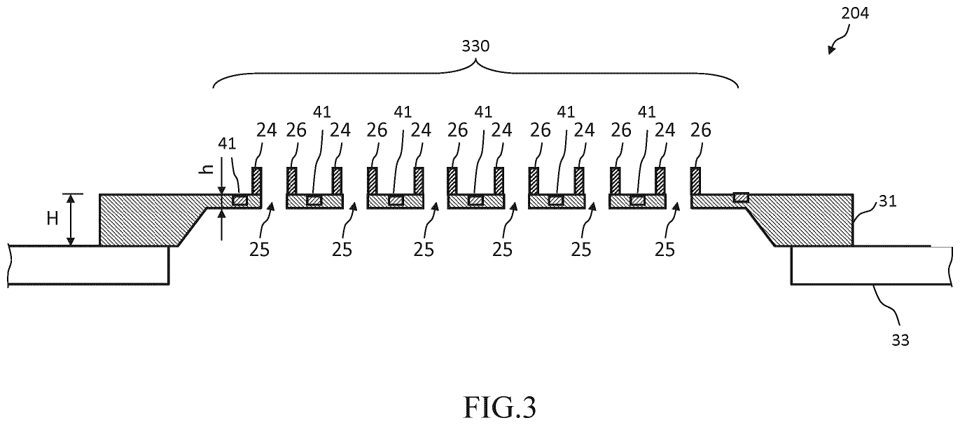

FIG. 3 is a sectional view showing a configuration of a blanking aperture array mechanism according to the first embodiment. In the blanking aperture array mechanism 204, as shown in FIG. 3, a blanking aperture array substrate 31 being a semiconductor substrate made of silicon, etc. is disposed on a support table 33. In a membrane region 330 at the center of the blanking aperture array substrate 31, a plurality of passage holes 25 (openings), through each of which a corresponding one of the multiple beams 20 passes, are formed at positions each corresponding to each hole 22 in the shaping aperture array substrate 203 shown in FIG. 2. A pair of a control electrode 24 and a counter electrode 26, (blanker: blanking deflector), is arranged in a manner such that the electrodes 24 and 26 are opposite to each other across a corresponding one of the plurality of the passage holes 25. A control circuit 41 (logic circuit) which applies a deflection voltage to the control electrode 24 for the passage hole 25 concerned is disposed, inside the blanking aperture array substrate 31, close to each corresponding passage hole 25. The counter electrode 26 for each beam is grounded.

In the control circuit 41, an amplifier (not shown) (an example of a switching circuit) is arranged. As an example of the amplifier, a CMOS (Complementary MOS) inverter circuit serving as a switching circuit is disposed. With regard to inputs (IN) to the CMOS inverter circuit, either an L (low) potential (e.g., ground potential) lower than a threshold voltage, or an H (high) potential (e.g., 1.5 V) higher than or equal to the threshold voltage is applied as a control signal. According to the first embodiment, in a state where an L potential is applied to the input (IN) of the CMOS inverter circuit, the output (OUT) of the CMOS inverter circuit, which is to be applied to the control circuit 41, becomes a positive potential (Vdd), and then, a corresponding beam is deflected by an electric field due to a potential difference from the ground potential of the counter electrode 26, and is controlled to be in a beam-off condition by being blocked by the limiting aperture substrate 206. In contrast, in a state (active state) where an H potential is applied to the input (IN) of the CMOS inverter circuit, the output (OUT) of the CMOS inverter circuit becomes a ground potential, and therefore, since there is no potential difference from the ground potential of the counter electrode 26, a corresponding beam is not deflected, and is controlled to be in a beam-on condition by passing through the limiting aperture substrate 206. Blanking control is provided by such deflection.

Next, operations of the writing mechanism 150 will be described. The electron beam 200 emitted from the electron gun 201 (emission source) almost perpendicularly (e.g., vertically) illuminates the whole of the shaping aperture array substrate 203 by the illumination lens 202. A plurality of rectangular holes 22 (openings) are formed in the shaping aperture array substrate 203. The region including all of the plurality of holes 22 is irradiated with the electron beam 200. For example, rectangular multiple beams (a plurality of electron beams) 20 are formed by letting portions of the electron beam 200 applied to the positions of the plurality of holes 22 individually pass through a corresponding one of the plurality of holes 22 in the shaping aperture array substrate 203. The multiple beams 20 individually pass through corresponding blankers of the blanking aperture array mechanism 204. The blanker provides blanking control such that a corresponding beam individually passing becomes in an ON condition during a set writing time (irradiation time).

The multiple beams 20 having passed through the blanking aperture array mechanism 204 are reduced by the reducing lens 205, and travel toward the hole in the center of the limiting aperture substrate 206. The electron beam which was deflected by the blanker of the blanking aperture array mechanism 204 deviates from the hole in the center of the limiting aperture substrate 206 and is blocked by the limiting aperture substrate 206. In contrast, the electron beam which was not deflected by the blanker of the blanking aperture array mechanism 204 passes through the hole in the center of the limiting aperture substrate 206 as shown in FIG. 1. Thus, the limiting aperture substrate 206 blocks each beam which was deflected to be in an OFF state by the blanker of the blanking aperture array mechanism 204. Then, each beam for one shot of the multiple beams 20 is formed by a beam which has been made during a period from becoming beam-on to becoming beam-off and has passed through the limiting aperture substrate 206. The multiple beams 20 having passed through the limiting aperture substrate 206 are focused by the objective lens 207 so as to be a pattern image of a desired reduction ratio. Then, all of the multiple beams 20 having passed through the limiting aperture substrate 206 are collectively deflected in the same direction by the main deflector 208 and the sub deflector 209 in order to irradiate respective beam irradiation positions on the target object 101. For example, when the XY stage 105 is continuously moving, tracking control is performed by the main deflector 208 so that the beam irradiation position may follow the movement of the XY stage 105. Ideally, the multiple beams 20 irradiating at a time are aligned at a pitch obtained by multiplying the arrangement pitch of a plurality of holes 22 in the shaping aperture array substrate 203 by the desired reduction ratio described above.

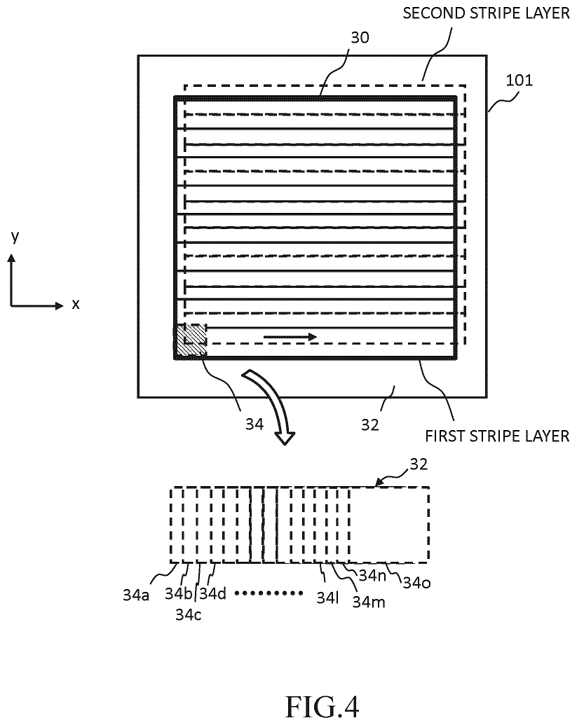

FIG. 4 is a conceptual diagram for explaining an example of a writing operation according to the first embodiment. As shown in FIG. 4, a writing region 30 (bold line) of the target object 101 is virtually divided into a plurality of stripe regions 32 by a predetermined width in the y direction, for example. In the case of FIG. 4, the writing region 30 of the target object 101 is divided in the y direction, for example, into a plurality of stripe regions 32 by the width size being substantially the same as the design size of an irradiation region 34 (writing field) that can be irradiated with one irradiation of the multiple beams 20.

FIG. 4 shows the case of performing multiple writing with multiplicity 2, for example. For the first writing processing, the first stripe layer composed of a plurality of stripe regions 32 obtained by dividing the writing region 30 is set. For the second writing processing, the second stripe layer composed of a plurality of stripe regions 32 obtained by shifting the position of the first stripe layer in the y direction is set. The shift amount in the y direction is set depending on the multiplicity, for example. Therefore, in the case of multiplicity N, for example, the position is preferably shifted by 1/N of the width of the stripe region 32. The multiplicity is not limited to 2, it may be 3 or more.

The direction of the positional deviation described above is not limited to the y direction. It is also preferable as shown in FIG. 4 to deviate in the x direction. Next, an example of the writing operation will be explained below.

First, the XY stage 105 is moved to make an adjustment such that the irradiation region 34 of the multiple beams 20 is located at the left end, or at a position further left than the left end, of the first stripe region 32 of the first stripe layer. Then, when performing writing to the first stripe region 32, the XY stage 105 is moved, for example, in the −x direction, so that the writing may proceed relatively in the x direction. The XY stage 105 is moved, for example, continuously at a constant speed. According to the first embodiment, during one movement (one pass) in the −x direction of the XY stage 105, all the first stripe regions 32 in each of the stripe layers are written.

After performing writing to the first stripe region 32 of the first stripe layer, the stage position is moved in the −y direction by, for example, ½ size of the width of the stripe region 32. Thereby, the stripe region 32 to be written is moved in the y direction by ½ size of the width of the stripe region 32, for example.

Next, an adjustment is made so that the irradiation region 34 of the multiple beams 20 can be located at the left end, or at a position further left than the left end, of the first stripe region 32 of the second stripe layer. By moving the XY stage 105, for example, in the −x direction, writing relatively proceeds in the x direction. Thereby, writing is performed to the first stripe region 32 of the second stripe layer. After performing writing to the first stripe region 32 of the second stripe layer, the second stripe region 32 of the first stripe layer is written. Thus, a corresponding stripe region 32 in each stripe layer is written in order. Hereafter, by repeating similar operations, all the stripe regions 32 in each stripe layer are to be written.

FIG. 4 shows the case where each stripe region 32 is written in the same direction, but, it is not limited thereto. For example, with respect to the stripe region 32 to be written following the stripe region 32 having already been written in the x direction, it may be written in the −x direction by moving the XY stage 105 in the x direction, for example. Thus, due to performing writing while alternately changing the writing direction, the stage moving time can be reduced, which results in reducing the writing time. By one shot of multiple beams having been formed by individually passing through the holes 22 in the shaping aperture array substrate 203, a plurality of shot patterns up to the number of the holes 22 are maximally formed at a time.

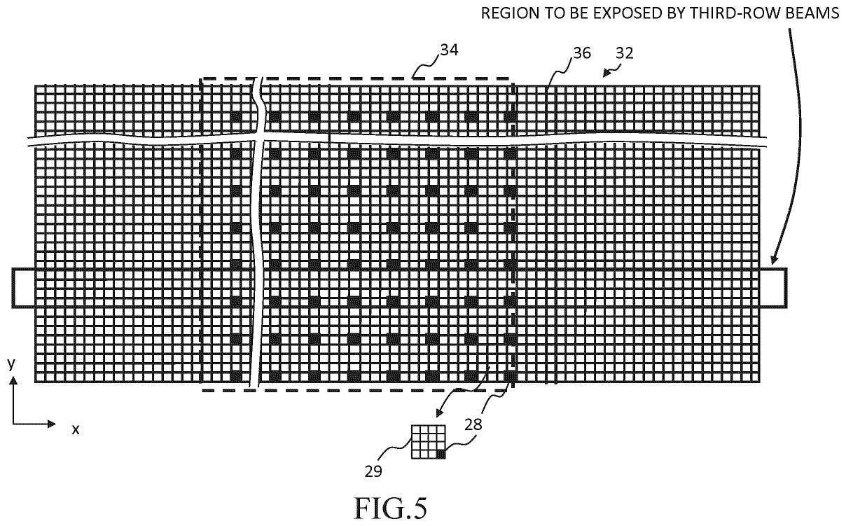

FIG. 5 is an illustration showing an example of an irradiation region of multiple beams and a pixel to be written (writing target pixel) according to the first embodiment. In FIG. 5, the stripe region 32 is divided into a plurality of mesh regions by the beam size of the multiple beams 20, for example. Each mesh region serves as a writing target pixel 36 (beam irradiation unit region, irradiation position). The size of the writing target pixel 36 is not limited to the beam size, and may be any size regardless of beam size. For example, it may be 1/n (n being an integer of 1 or more) of the beam size. FIG. 5 shows the case where the writing region of the target object 101 is divided, for example, in the y direction, into a plurality of stripe regions 32 by the width size being substantially the same as the size of the irradiation region 34 (writing field) that can be irradiated with one irradiation of the multiple beams 20. The x-direction size of the rectangular, including square, irradiation region 34 can be defined by (the number of x-direction beams)×(beam pitch in the x direction). The y-direction size of the rectangular irradiation region 34 can be defined by (the number of y-direction beams)×(beam pitch in the y direction). FIG. 5 shows the case of multiple beams of 512×512 (rows×columns) having been simplified to 8×8 (rows×columns). In the irradiation region 34, there are shown a plurality of pixels 28 (beam writing positions) that can be irradiated with one shot of the multiple beams 20. The pitch between adjacent pixels 28 is the beam pitch of the multiple beams. A sub-irradiation region 29 (pitch cell region) is configured by a rectangular, including square, region surrounded by the size of beam pitches in the x and y directions. In the example of FIG. 5, each sub-irradiation region 29 is composed of 4×4 pixels, for example.

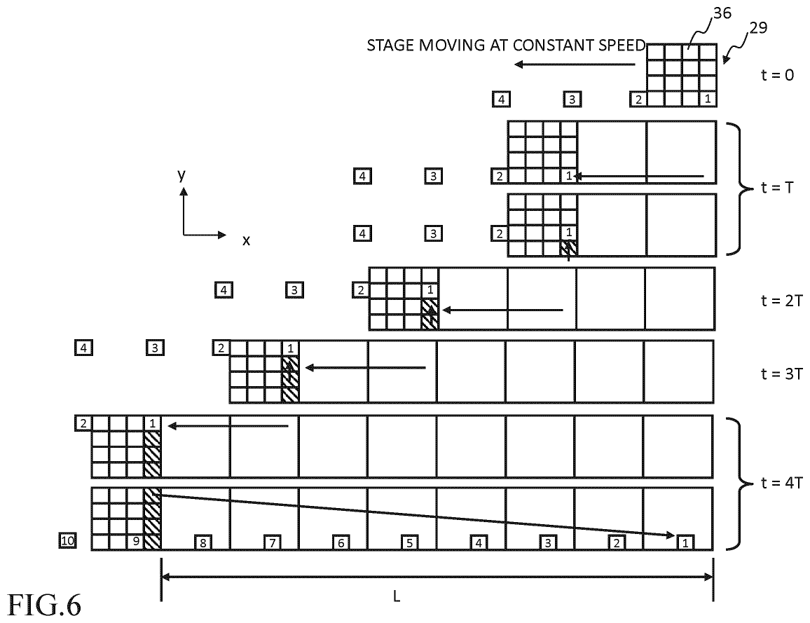

FIG. 6 is an illustration for explaining an example of a multi-beam writing operation according to the first embodiment. FIG. 6 shows the case where the inside of each sub-irradiation region 29 is written with four different beams. Furthermore, the example of FIG. 6 shows a writing operation where the XY stage 105 continuously moves at the speed at which the XY stage 105 moves the distance L of eight beam pitches while a ¼ region, namely the region of 1/(the number of beams used for irradiation), in each sub-irradiation region 29 is written. In the writing operation shown in FIG. 6, for example, while the XY stage 105 moves the distance L of eight beam pitches, different four pixels in the same sub-irradiation region 29 are written (exposed) by being applied with four shots of the multiple beams 20 at a shot cycle T with shifting the irradiation position (pixel 36) in order by the sub deflector 209. In order that the relative position between the irradiation region 34 and the target object 101 may not be shifted by the movement of the XY stage 105 while these four pixels 36 are written (exposed), the irradiation region 34 is made to follow the movement of the XY stage 105 by collective deflection of all of the multiple beams 20 by the main deflector 208. In other words, a tracking control is performed. After one tracking cycle is completed, tracking is reset to return to the previous (last) tracking starting position. Since writing of the pixels in the first column from the right of each sub-irradiation region 29 has been completed, in the next tracking cycle after resetting the tracking, first, the sub deflector 209 provides deflection such that the beam writing position is adjusted (shifted) to write the second pixel column from the right still not having been written in each sub-irradiation region 29, for example. By repeating this operation during writing the stripe region 32, as shown in the lower part of FIG. 4, the position of the irradiation region 34 of the multiple beams 20 is sequentially moved (shifted), such as the irradiation region 34a, 34b, 34c, . . . 34o, to perform writing.

As described above, in multi-beam writing, since writing is executed while individually performing blanking processing on multiple beams, the number of beams to be blanking-processed changes during the writing. When the number of beams changes, the total current amount also changes, which results in generating a so-called beam blur due to the Coulomb effect, etc., or shifting of the beam irradiation position due to charging in the column.

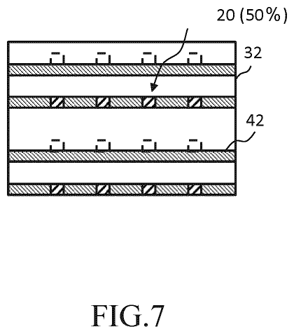

FIG. 7 is an illustration showing an example of a beam pitch and a pattern pitch according to the first embodiment.

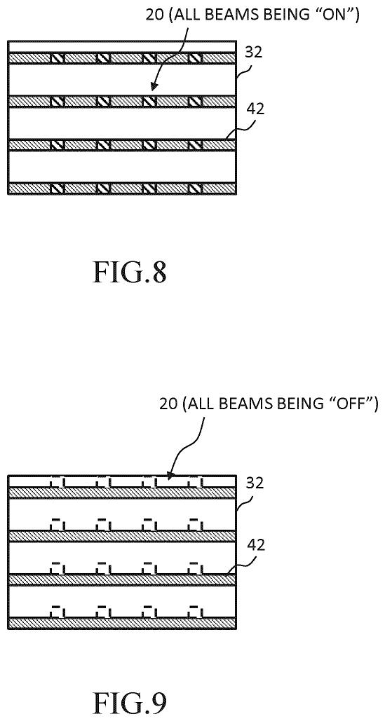

FIG. 8 is an illustration showing another example of a beam pitch and a pattern pitch according to the first embodiment.

FIG. 9 is an illustration showing another example of a beam pitch and a pattern pitch according to the first embodiment.

FIG. 7 shows an example of the case where the beam pitch of the multiple beams 20 and the pattern pitch of the pattern 42 are inconsistent with each other. Generally, in a layout of a chip pattern to be written, as shown in FIG. 7, the beam pitch of the multiple beams 20 and the pattern pitch of the pattern 42 are inconsistent with each other in many cases. When the beam pitch of the multiple beams 20 and the pattern pitch of the pattern 42 are inconsistent, change of the number of blanking beams for each shot is small.

In contrast, FIG. 8 shows the case where the beam pitch of the multiple beams 20 and the pattern pitch of the pattern 42 are consistent with each other. FIG. 8 shows an example of all the beams in a shot are ON beams. There is a possibility for the case of FIG. 8 that all the beams turn into OFF beams in the next shot as shown in FIG. 9. Thus, when the beam pitch of the multiple beams 20 and the pattern pitch of the pattern 42 are consistent with each other, change of the number of blanking beams for each shot is very large.

As shown in FIGS. 8 and 9, the irradiation position of the multiple beams 20 may deviate depending on the number of blanking beams of each shot, without limiting to the case of beam-on of 100% changing to 0%.

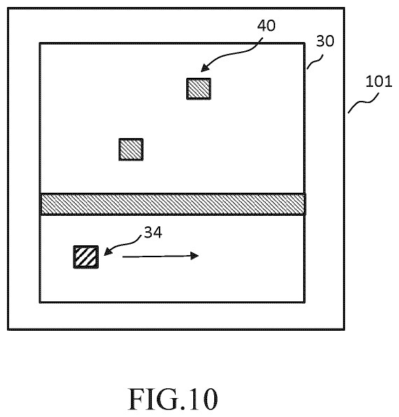

FIG. 10 is an illustration showing an example of a region where the pattern density is specifically high according to the first embodiment. FIG. 10 shows the case where a plurality of regions 40 whose pattern density is specifically high exist in the writing region 30 of a chip pattern to be written. When writing the region 40 whose pattern density is specifically high, there is a tendency that shifting of the irradiation position of a beam depending on the number of beams to be blanking-processed easily occurs.

Therefore, it is desirable, according to the number of blanking beams for each shot, to correct the irradiation position of the multiple beams 20. The case of a pattern layout where the region 40 whose pattern density is specifically high exists as shown in FIG. 10 is very few compared to the case of a pattern layout where the region 40 whose pattern density is specifically high does not exist. In the pattern layout where there is no region 40 whose pattern density is specifically high, correction processing is unnecessary or simple correction can be allowed. Here, if the number of blanking beams for each shot is calculated for all the shots, and individual correction depending on the calculated number is performed for each shot, a large load is applied to calculation processing. Therefore, it is desirable to evaluate whether the chip pattern is the one which needs individual correction for each shot, or the one which needs no correction processing or simple correction. According to the first embodiment, it is determined whether the chip pattern is the one which needs individual correction for each shot, or the one which needs no correction processing or simple correction. Then, correction is performed as needed. It is specifically described below.

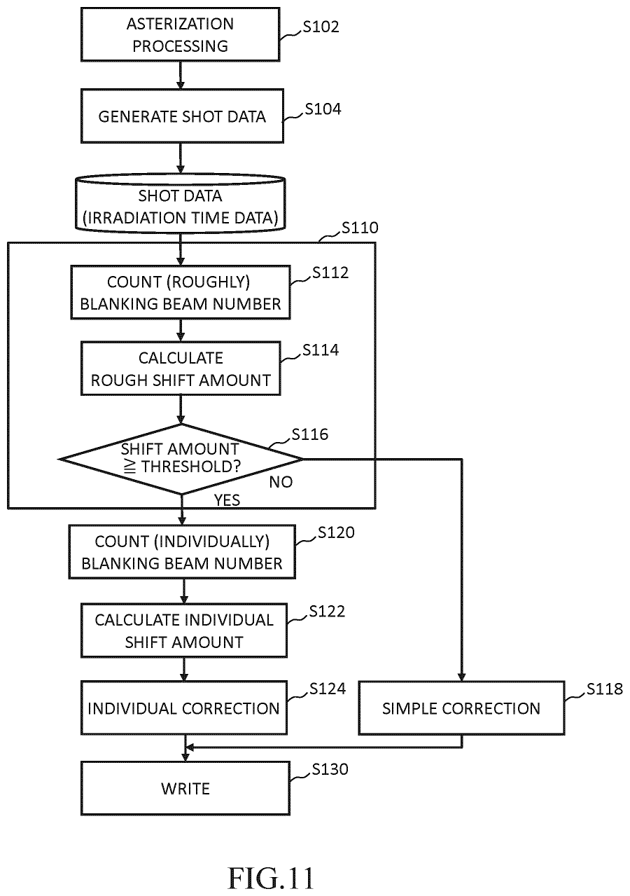

FIG. 11 is a flowchart showing an example of main steps of a writing method according to the first embodiment. In FIG. 11, the writing method of the first embodiment executes a series of steps: a rasterization processing step (S102), a shot data generation step (S104), an estimation step (S110), a simple correction step (S118), a blanking beam number counting (individual) step (S120), an individual shift amount calculation step (S122), an individual correction step (S124), and a writing step (S130). Furthermore, the estimation step (S110) executes, as internal steps, a blanking beam number counting (rough) step (S112), a rough shift amount calculation step (S114), and a determination step (S116).

In the rasterization processing step (S102), the rasterization processing unit 50 reads chip pattern data (writing data) from the storage device 140, and performs rasterization processing. Specifically, pattern density (pattern area density) is calculated for each pixel 36.

In the shot data generation step (S104), first, the shot data generation unit 52 calculates, for each pixel 36, a dose D with which the pixel 36 concerned is irradiated. For example, the dose D can be calculated by multiplying a preset base dose D_{base}, a proximity effect correction irradiation coefficient Dₚ, and a pattern area density ρ. Thus, it is preferable to obtain the dose D to be in proportion to a pattern area density calculated for each pixel 36. With respect to the proximity effect correction irradiation coefficient Dₚ, the writing region (e.g., in this case, stripe region 32) is virtually divided into a plurality of proximity mesh regions (mesh regions for proximity effect correction calculation) by a predetermined size. The size of the proximity mesh region is preferably set to be about 1/10 of the influence range of the proximity effect, such as about 1 μm. Then, writing data is read from the storage device 140, and, for each proximity mesh region, a pattern density ρ′ (pattern area density) of a pattern arranged in the proximity mesh region concerned is calculated.

Next, a proximity effect correction irradiation coefficient Dₚ for correcting a proximity effect is calculated for each proximity mesh region. Here, the size of the mesh region to calculate the proximity effect correction irradiation coefficient Dₚ does not need to be the same as that of the mesh region to calculate a pattern density ρ′. Furthermore, a correction model of the proximity effect correction irradiation coefficient Dₚ and its calculation method may be the same as those used in the conventional single beam writing system.

The shot data generation unit 52 calculates, for each pixel 36, an irradiation time “t” of an electron beam for applying a calculated dose D to the pixel 36 concerned. The irradiation time “t” can be obtained by dividing the dose D by a current density J. Thereby, a dose map (actually, an irradiation time map) in which irradiation time data (shot data) for each pixel 36 is defined is generated.

In the case of performing multiple writing, a dose map (actually, an irradiation time map) is generated for each writing processing of each time of multiple writing. In other words, a dose map (actually, an irradiation time map) is generated for each stripe layer. The generated irradiation time data is stored in the storage device 142 in the order of shots.

In the estimation step (S110), the estimation unit 54 estimates, with respect to each of all the shots, whether it is individually necessary to perform a correction of a positional deviation caused by the number of blanking beams. It is specifically described below.

In the blanking beam number counting (rough) step (S112), the blanking beam number counting unit 56 calculates, using shot data of the multiple beams 20, the number of blanking beams controlled to be beam-off in some of all the shots of the multiple beams 20 to be applied to the target object 101 (substrate). Preferably, the number of blanking beams is calculated as a rate (%) to the number of applicable beams in all the multiple beams 20. The sampling method of some shots to calculate the number of blanking beams is not particularly limited. It may be randomly sampled, or appropriately sampled depending on a density (roughness/fineness) of a writing pattern. For example, when some pixels in a pitch cell are randomly written in each tracking, the number of blanking beams in a specific tracking can be calculated.

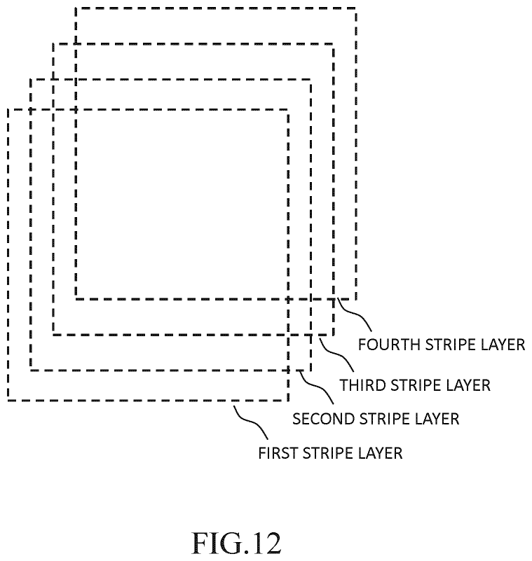

FIG. 12 is an illustration showing an example of a stripe layer of multiple writing according to the first embodiment. FIG. 12 shows the case of multiple writing with multiplicity 4, namely four-time writing. According to the first embodiment, the number of blanking beams is calculated, for example, for each shot for one stripe layer in a plurality of stripe layers for multiple writing. Thereby, in the case of multiple writing with multiplicity 4, namely four-time writing, the amount of calculation processing can be reduced to ¼.

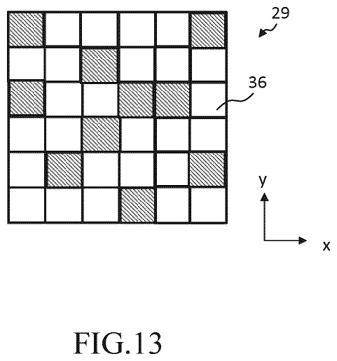

FIG. 13 is an illustration showing an example of a sub-irradiation region according to the first embodiment. FIG. 13 shows the case where each sub-irradiation region 29 is composed of 6×6 pixels. For completing writing processing of one time in multiple writing in such each sub-irradiation region 29, thirty-six (6×6) times of shots are needed. Therefore, if, for example, each sub-irradiation region 29 is composed of 10×10 pixels, one hundred times of shots are needed. That is, in writing processing of one time in multiple writing, one hundred times of shots are performed for a plurality of pixels (in this case, one hundred pixels) located in the irradiation region 34 of the multiple beams 20. Thus, even in writing processing of one time in multiple writing, it turns out that a huge number of shots are performed for the whole of the target object 101. If each step processing of the estimation step (S110) is carried out with respect to all the shots in writing processing of one time in multiple writing, the amount of calculation processing is still quite large. Then, it is also preferable to extract some pixels which have been preset or randomly set from a plurality of pixels in each sub-irradiation region 29, and to calculate the number of blanking beams for each of a plurality of shots to be applied to the extracted pixels. By this, the amount of calculation processing can further be reduced. The example of FIG. 13 shows ten pixels 36 randomly set for calculating the number of blanking beams, in thirty-six (6×6) pixels.

It is also preferable that, in the writing step (S130) to be described later, for example, a preset maximum irradiation time of one shot is divided into a plurality of sub-irradiation time whose irradiation time differs from each other, and for each shot, at least one combination of sub shots in sub shots of the plurality of sub-irradiation time apples irradiation such that the irradiation time of each beam becomes a desired irradiation time. In such a case, it is also preferable to extract only a sub shot having the maximum sub irradiation time, and to calculate the number of blanking beams of the extracted sub shot.

Alternatively, in the case of controlling the irradiation time by a counter system, it is also preferable to calculate an average number of blanking beams in a certain period.

In the rough shift amount calculation step (S114), the shift amount calculation unit 58 calculates, for each shot of some shots for which the number of blanking beams has been calculated, a rough shift amount (an example of the first positional deviation shift amount) depending on the number of blanking beams of the shot concerned, shifted from the design position of the multiple beams 20.

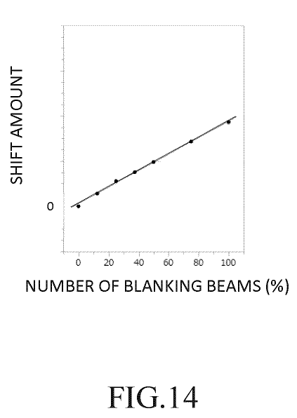

FIG. 14 is an illustration showing an example of a relationship between a shift amount and the number of blanking beams according to the first embodiment. In FIG. 14, the ordinate axis represents a shift amount, and the abscissa axis represents a rate of the number of blanking beams. FIG. 14 shows a relationship between a shift amount and a rate of the number of blanking beams when the number of blanking beams is uniformly changed by a beam array. As shown in FIG. 14, there is a linear relation between the shift amount and the rate of the number of blanking beams. In the example of FIG. 14, the shift amount is in proportion to the rate of the number of blanking beams, for example. Then, the shift amount calculation unit 58 calculates a rough shift amount Δx(Si) of a representative shot Si by multiplying a blanking beam number Pr, calculated in a representative shot Si of some shots for which the number of blanking beams was calculated, by a correlation coefficient “a”. The rough shift amount Δx (Si) can be defined by the following equation (1). “i” indicates the index of a representative shot. Not only with respect to the x direction, a rough shift amount Δy(Si) is similarly calculated with respect to the y direction.

$$Δ x ( Si ) = Pr \cdot a \qquad ( 1 )$$

Although the example described above shows the case where the number of blanking beams is counted for the whole of the sub-irradiation region 29, it is not limited thereto.

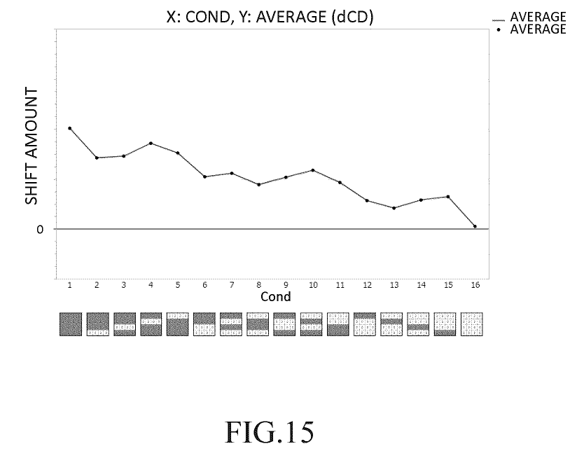

FIG. 15 is an illustration showing another example of a relationship between a shift amount and the number of blanking beams according to the first embodiment. In FIG. 15, the ordinate axis represents a shift amount, and the abscissa axis represents a combination of sub regions. FIG. 15 shows an example of an average value of a shift amount in each of sixteen combinations obtained by combining sub regions_which are acquired by dividing the region of a beam array configuring the multiple beams 20 by four in the y direction. FIG. 15 shows an example of an average value of a shift amount in changing the region for blanking by a beam array. As shown in FIG. 15, the average value of shift amounts varies depending on the combination. Then, when calculating the number of blanking beams, the blanking beam number counting unit 56 divides the region of the beam array configuring multiple beams into a plurality of sub regions, and calculates the number of blanking beams for each of the sub regions. It is also preferable that the shift amount calculation unit 58 calculates a rough shift amount for each sub region. Thereby, a rough shift amount based on the position of a sub region can be obtained.

In the determination step (S116), the determination unit 60 determines, for each shot, whether there is a shot with respect to which the rough shift amount exceeds a threshold value. Specifically, the determination unit 60 determines whether there is a rough shift amount exceeding a threshold Th1 in rough shift amounts of respective shots. When there is no shot with respect to which the rough shift amount exceeds the threshold Th1, it proceeds to the simple correction step (S118). When there is a shot with respect to which the shift amount exceeds the threshold Th1, it proceeds to the blanking beam number counting (individual) step (S120). Thereby, it is possible to determine, with respect to all the shots, whether the layout is the one of a chip pattern in need of individual correction, or the one of a chip pattern in need of simple correction.

In the simple correction step (S118), when there is no shot exceeding a threshold value, the correction amount calculation unit 65 calculates a correction amount, which is common to all the shots, for an irradiation position, based on a rough shift amount. Then, when there is no rough shift amount exceeding the threshold Th1, the correction unit 66 corrects, with respect to all the shots, the same simple shift amount (an example of the third positional deviation shift amount), as a common correction amount for an irradiation position. As the simple shift amount, the threshold Th1 is used, for example. Alternatively, it is also preferable to use, for example, a statistic value of a plurality of obtained rough shift amounts. For example, an average, a maximum, a minimum, or a median is used.

When there is no rough shift amount exceeding the threshold Th1, what is needed is just to apply simple correction to the whole. Therefore, the blanking beam number counting (individual) step (S120), the individual shift amount calculation step (S122), and the individual correction step (S124) can be omitted.

In the blanking beam number counting (individual) step (S120) (fine counting step), when there is a shot exceeding a threshold value, the blanking beam number counting unit 62 calculates the number of blanking beams controlled to be beam-off in remaining shots in all the shots described above. In other words, when there is a rough shift amount exceeding the threshold Th1, the blanking beam number counting unit 62 calculates the number of blanking beams in at least remaining shots in all the shots. Furthermore, it is also acceptable to newly calculate the number of blanking beams of each shot of all the shots.

In the individual shift amount calculation step (S122), the shift amount calculation unit 64 calculates an individual shift amount (an example of the second positional deviation shift amount) in all shots, depending on the calculated number of blanking beams, shifted from the design position of the multiple beams 20. Specifically, when there is a rough shift amount exceeding the threshold Th1, the shift amount calculation unit 64 calculates, with respect to all the shots, an individual shift amount (an example of the second positional deviation shift amount) depending on the calculated number P(sj) of blanking beams of the shot concerned, shifted from the design position of the multiple beams 20. The shift amount calculation unit 64 calculates an individual shift amount Δx(sj) for the concerning shot sj by multiplying the number P(sj) of blanking beams calculated for each shot sj by a correlation coefficient “a”. The individual shift amount Δx(sj) can be defined by the following equation (2). “j” indicates the index of a shot concerned in all the shots. Not only with respect to the x direction, an individual shift amount Δy(sj) is similarly calculated with respect to the y direction.

$$Δ x ( sj ) = P ( sj ) \cdot a \qquad ( 2 )$$

In the individual correction step (S124), the correction amount calculation unit 65 calculates an amount of correction of an irradiation position of each shot, based on the calculated individual shift amount. When there is a rough shift amount exceeding the threshold Th1, the correction unit 66 individually corrects, with respect to all the shots, an individual shift amount in the shot concerned, based on the amount of correction of the irradiation position of each shot.

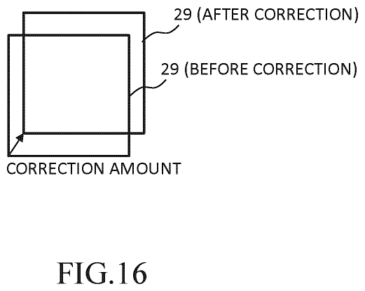

FIG. 16 is an illustration for explaining an example of a correction method according to the first embodiment. As shown in FIG. 16, correction of an irradiation position of each shot is performed, for both the simple correction step (S118) and the individual correction step (S124), by correcting the positions to which the multiple beams 20 are deflected. The correction amount is applied in the direction which is the one each shift amount (a rough shift amount or an individual shift amount) is corrected. In other words, a deflection position is corrected in the direction, opposite to that of a calculated shift amount, by the same amount as the calculated shift amount.

Alternatively, it is also preferable to correct an irradiation position of each shot by correcting the position of the figure pattern defined in the writing data. In that case, the rasterization processing step (S102) and the shot data generation step (S104) may be newly performed after the correction.

In the writing step (S130), under the control of the writing control unit 72, the writing mechanism 150 applies shots of the multiple beams 20 to the above-described irradiation positions of respective shots each corrected using the calculated correction amount. In other words, the writing mechanism 150 applies shots of multiple beams to respective shot positions on the target object 101, according to existence or nonexistence of a rough shift amount exceeding the threshold Th1. That is, with respect to all the shots, if there is a shot of a rough shift amount exceeding the threshold Th1, shots of multiple beams are individually applied to respective positions where a shift amount depending on the number of blanking beams has been corrected. If, in all the shots, there is no shot with respect to which the rough shift amount exceeds the threshold Th1, shots of multiple beams are applied to respective positions where a common rough shift amount has been corrected.

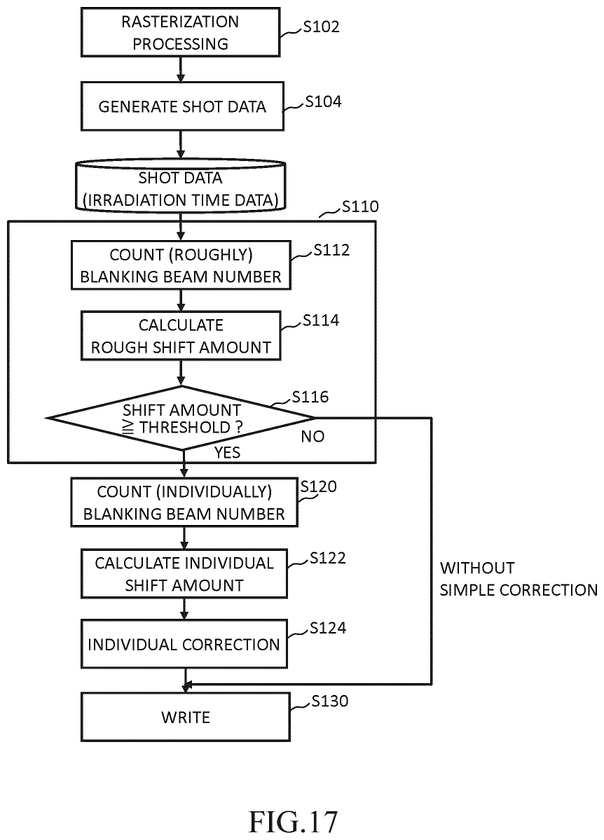

FIG. 17 is a flowchart showing an example of main steps of a writing method according to a modified example of the first embodiment. The contents of the main steps of the writing method according to the modified example in FIG. 17 are the same as those of FIG. 11 except that the simple correction step (S118) is omitted.

In the modified example, under the control of the writing control unit 72, if there is no shot exceeding the threshold Th1, the writing mechanism 150 applies shots of the multiple beams 20 to irradiation positions of respective shots without correcting the irradiation positions. In other words, if there is no rough shift amount exceeding the threshold Th1, with respect to all the shots, the writing mechanism 150 applies shots of multiple beams 20 to respective shot positions on the target object 101 without correcting an individual shift amount depending on the number of blanking beams.

As described above, when there is no rough shift amount exceeding the threshold Th1, writing can be performed even without carrying out simple correction. By appropriately adjusting a method for setting the threshold Th1, simple correction can also be omitted.

As described above, according to the first embodiment, it is possible to reduce a load on calculation processing with respect to coping with positional deviation depending on the number of beams for each shot in multi-beam writing.

### Second Embodiment

The first embodiment has described the configuration where, in the estimation step (S110), an estimation is performed whether individual correction using the number of blanking beams of some representative shots is necessary. However, the estimation method is not limited thereto. A second embodiment will describe a configuration where estimation is performed using a pattern density. The contents of the second embodiment may be the same as those of the first embodiment except for what is particularly described below.

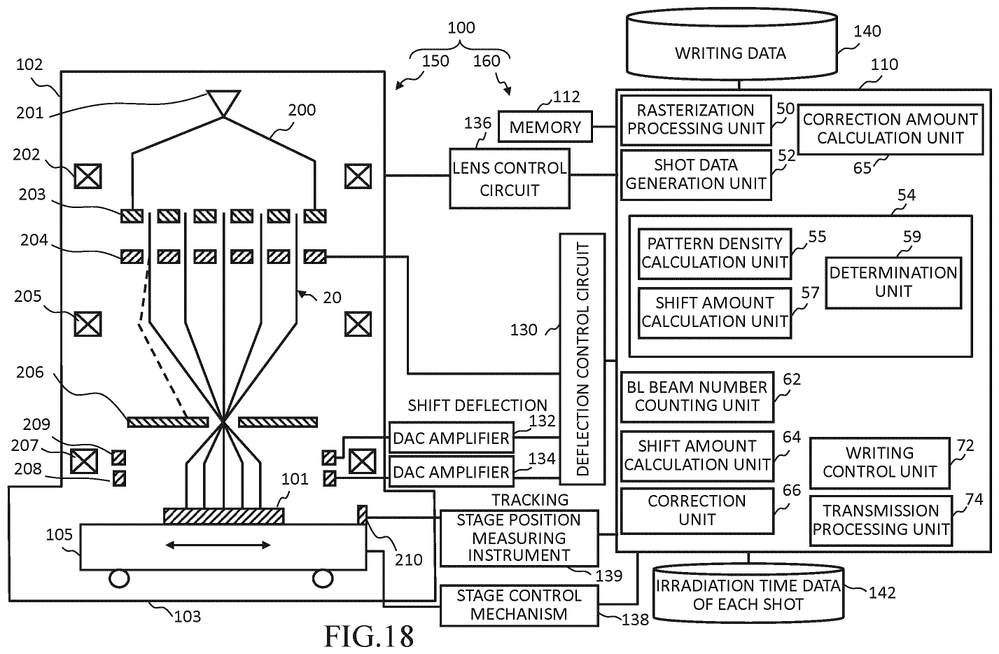

FIG. 18 is a conceptual diagram showing a configuration of a writing apparatus according to the second embodiment. FIG. 18 is the same as FIG. 1 except that, in the estimation unit 54, there are arranged a pattern density calculation unit 55, a shift amount calculation unit 57, and a determination unit 59 instead of the blanking beam number counting unit 56, the shift amount calculation unit 58, and the determination unit 60. Each of the “ . . . units” such as the rasterization processing unit 50, the shot data generation unit 52, the estimation unit 54 (the pattern density calculation unit 55, the shift amount calculation unit 57, and the determination unit 59), the blanking beam number counting unit 62, the shift amount calculation unit 64, the correction amount calculation unit 65, the correction unit 66, the writing control unit 72, and the transmission processing unit 74 includes processing circuitry. The processing circuitry includes, for example, an electric circuit, a computer, a processor, a circuit board, a quantum circuit, a semiconductor device, or the like. Each “ . . . unit” may use common processing circuitry (the same processing circuitry), or different processing circuitry (separate processing circuitry). Information input/output to/from the rasterization processing unit 50, the shot data generation unit 52, the estimation unit 54 (the pattern density calculation unit 55, the shift amount calculation unit 57, and the determination unit 59), the blanking beam number counting unit 62, the shift amount calculation unit 64, the correction amount calculation unit 65, the correction unit 66, the writing control unit 72, and the transmission processing unit 74, and information being operated are stored in the memory 112 each time.

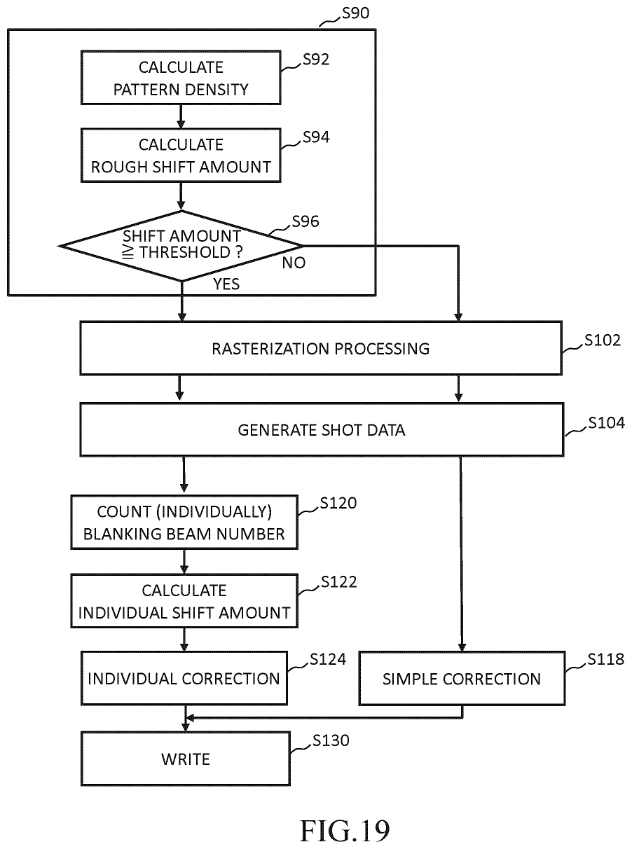

FIG. 19 is a flowchart showing an example of main steps of a writing method according to the second embodiment. In FIG. 19, the writing method of the second embodiment executes a series of steps: an estimation step (S90), a rasterization processing step (S102), a shot data generation step (S104), a simple correction step (S118), a blanking beam number counting (individual) step (S120), an individual shift amount calculation step (S122), an individual correction step (S124), and a writing step (S130). Furthermore, the estimation step (S90) executes, as internal steps, a pattern density calculation step (S92), a rough shift amount calculation step (S94), and a determination step (S96).

In the estimation step (S90), the estimation unit 54 estimates, with respect to all the shots, whether it is necessary to individually correct a positional deviation shift caused by the number of blanking beams. It is specifically described below.

In the pattern density calculation step (S92), using pattern data in which a plurality of figure patterns are defined, the pattern density calculation unit 55 acquires a pattern density of each of a plurality of processing regions which are obtained by dividing the writing region 30 of the target object 101. Specifically, the pattern density calculation unit 55 reads writing data from the storage device 140, and calculates a pattern density of each of a plurality of processing regions which are obtained by virtually dividing the writing region 30 into mesh-like regions by a predetermined size. The size of the processing region is preferably the same as that of the irradiation region 34 of the multiple beams 20, for example. However, it is not limited thereto. The size of the processing region may be larger than the irradiation region 34, or smaller than it. For example, the pixel 36 to be used in the rasterization processing described later may be used as the processing region. Alternatively, it is also preferable to previously perform the rasterization processing step (S102), and then, to use the result of the step S102. Alternatively, it is also preferable to define a pattern density map in advance in the writing data by off-line as additional information, and to acquire a pattern density by reading the pattern density map.

In the rough shift amount calculation step (S94), the shift amount calculation unit 57 calculates, for each processing region, a shift amount (another example of the first positional deviation shift amount) depending on a pattern density, shifted from the design position of the multiple beams 20 in the case of applying a shot to the target object 101 with the multiple beams 20.

The shift amount calculation unit 57 calculates a rough shift amount Δx(Ri) in a processing region Ri by multiplying a pattern density Di, calculated in the processing region Ri, by a correlation coefficient “b”. The rough shift amount Δx(Ri) can be defined by the following equation (3). “i” indicates the index of a processing region. Not only with respect to the x direction, a rough shift amount Δy(Ri) is similarly calculated with respect to the y direction.

$$Δ x ( R i ) = Di \cdot b \qquad ( 3 )$$

In the determination step (S96), the determination unit 59 determines, for respective processing regions, whether there is a processing region with respect to which the rough shift amount exceeds a threshold value. In other words, the determination unit 59 determines whether there is a rough shift amount exceeding a threshold Th2 in rough shift amounts of respective processing regions. When there is no processing region with respect to which the rough shift amount exceeds the threshold Th2, it proceeds to the simple correction step (S118) through the rasterization processing step (S102) and the shot data generation step (S104). When there is a processing region with respect to which the rough shift amount exceeds the threshold Th2, it proceeds to the blanking beam number counting (individual) step (S120) through the rasterization processing step (S102) and the shot data generation step (S104).

The contents of the rasterization processing step (S102) and the shot data generation step (S104) are the same as those of the first embodiment.

In the simple correction step (S118), when there is no processing region exceeding a threshold value, the correction amount calculation unit 65 calculates a correction amount, which is common to all the shots, for an irradiation position, based on a rough shift amount. Then, when there is no rough shift amount exceeding the threshold Th2, the correction unit 66 corrects, with respect to all the shots, the same predetermined simple shift amount (another example of the third positional deviation shift amount), as a common correction amount for an irradiation position. As the simple shift amount, preferably, the threshold Th2 is used, for example. Alternatively, it is also preferable to use a statistic value of calculated rough shift amounts. As the statistic value, for example, a maximum, a minimum, an average, or a median is used. Alternatively, the threshold Th1 described in the first embodiment may be used. Furthermore, the threshold Th1 and the threshold Th2 may be the same value.

The contents of each of the blanking beam number counting (individual) step (S120), the individual shift amount calculation step (S122), and the individual correction step (S124) are the same as those of the first embodiment. According to the second embodiment, in the blanking beam number counting (individual) step (S120), when there is a processing region exceeding a threshold value, the blanking beam number counting unit 62 calculates the number of blanking beams of all the shots to be applied to the substrate with the multiple beams 20.

In the writing step (S130), the writing mechanism 150 applies shots of the multiple beams 20 to respective positions on the target object 101, each position depending on the existence or nonexistence of a rough shift amount exceeding the threshold Th2.

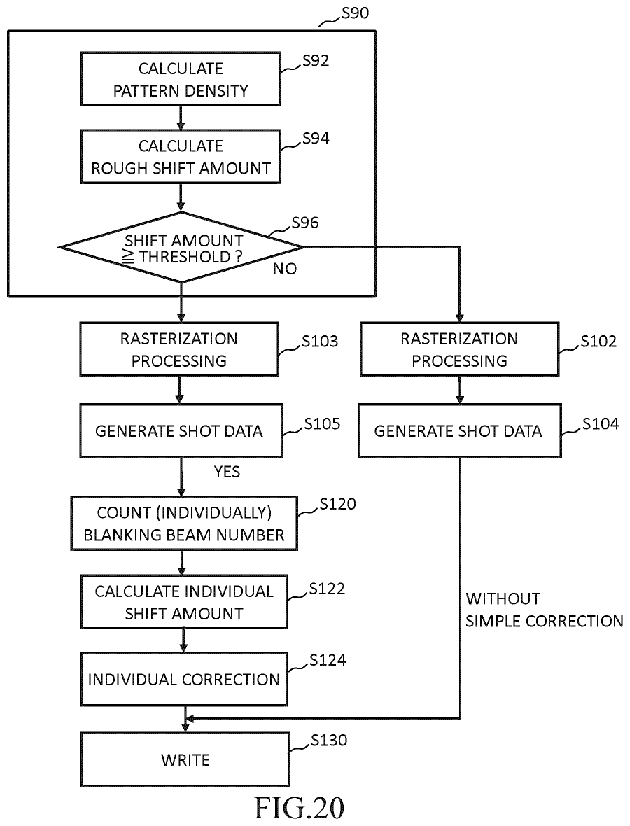

FIG. 20 is a flowchart showing an example of main steps of a writing method according to a modified example of the second embodiment. FIG. 20 is the same as FIG. 19 except that the simple correction step (S118) is omitted.

In the modified example, under the control of the writing control unit 72, if there is no processing region exceeding a threshold value, the writing mechanism 150 applies shots of the multiple beams 20 to irradiation positions of respective shots without correcting the irradiation positions. In other words, if there is no rough shift amount exceeding the threshold Th2, with respect to all the shots, the writing mechanism 150 applies shots of multiple beams 20 to respective shot positions on the target object 101 without correcting an individual shift amount depending on the number of blanking beams.

As described above, when there is no rough shift amount exceeding the threshold Th2, writing can be performed even without carrying out simple correction. By appropriately adjusting a method for setting the threshold Th2, simple correction can also be omitted.

As described above, according to the second embodiment, it is possible, using a pattern density as an index, to reduce a load on calculation processing with respect to coping with positional deviation depending on the number of beams for each shot in multi-beam writing.

Functions of processing described in each embodiment may be executed by a computer. A program for causing a computer to implement such functions of processing may be stored in a non-transitory tangible computer-readable storage medium such as a magnetic disk drive.

While the apparatus configuration, control method, and the like not directly necessary for explaining the present invention are not described, some or all of them can be appropriately selected and used on a case-by-case basis when needed. For example, although description of the configuration of the control unit for controlling the writing apparatus 100 is omitted, it should be understood that some or all of the configuration of the control unit can be selected and used appropriately when necessary.

Furthermore, any multi-charged particle beam writing apparatus, multi-charged particle beam writing method, and program that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A multi-charged particle beam writing method comprising:
calculating, using shot data of multiple charged particle beams, a number of blanking beams controlled to be beam-off in some shots in all shots of the multiple charged particle beams to be applied to a substrate;
calculating, for each shot of the some shots, a first positional deviation shift amount depending on the number of blanking beams of a shot concerned, shifted from a design position of the multiple charged particle beams;
determining, for the each shot of the some shots, whether there is a shot with respect to which the first positional deviation shift amount exceeds a threshold value;
calculating, in a case of there being a shot exceeding the threshold value, a number of blanking beams controlled to be beam-off in remaining shots in the all shots;
calculating a second positional deviation shift amount depending on a calculated number of blanking beams in the all shots, shifted from the design position of the multiple charged particle beams;
calculating a correction amount for an irradiation position of the each shot, based on a calculated second positional deviation shift amount; and
applying a shot of the multiple charged particle beams to the irradiation position of the each shot, which has been corrected using a calculated correction amount.

2. The method according to claim 1, further comprising:
calculating, in a case of there being no shot exceeding the threshold value, a correction amount, which is common to the all shots, for the irradiation position, based on the first positional deviation shift amount.

3. The method according to claim 1, wherein, in a case of there being no shot exceeding the threshold value, the shot of the multiple charged particle beams is applied to the irradiation position of the each shot without correcting the irradiation position.

4. The method according to claim 1, wherein, in a case of calculating the number of blanking beams, a region of a beam array configuring the multiple charged particle beams is divided into a plurality of sub regions, and the number of blanking beams is calculated for each of the plurality of sub regions.

5. The method according to claim 1, wherein correcting the irradiation position of the each shot is performed by correcting a position of a figure pattern defined in writing data.

6. The method according to claim 1, wherein correcting the irradiation position of the each shot is performed by correcting positions to which the multiple charged particle beams are deflected.

7. A multi-charged particle beam writing method comprising:
acquiring, using pattern data defining a plurality of figure patterns, a pattern density of each of a plurality of regions obtained by dividing a writing region of a substrate;
calculating, for the each of the plurality of regions, a first positional deviation shift amount depending on the pattern density, shifted from a design position of multiple charged particle beams, in a case of applying a shot to the substrate with the multiple charged particle beams;
determining, for the each of the plurality of regions, whether there is a region with respect to which the first positional deviation shift amount exceeds a threshold value;
calculating, in a case of there being a region exceeding the threshold value, a number of blanking beams controlled to be beam-off in all shots to be applied to the substrate with the multiple charged particle beams;
calculating a second positional deviation shift amount depending on a calculated number of blanking beams, shifted from the design position of the multiple charged particle beams;
calculating, in a case of there being the first positional deviation shift amount exceeding the threshold value, a correction amount for an irradiation position of each shot, based on the second positional deviation shift amount in a shot concerned, with respect to the all shots; and
applying a shot of the multiple charged particle beams to the irradiation position of the each shot, which has been corrected using a calculated correction amount.

8. The method according to claim 7, further comprising:
calculating, in a case of there being no region exceeding the threshold value, a correction amount, which is common to the all shots, for the irradiation position, based on the first positional deviation shift amount.

9. The method according to claim 7, wherein, in a case of there being no region exceeding the threshold value, the shot of the multiple charged particle beams is applied to the irradiation position of the each shot without correcting the irradiation position.
